(19) United States
(12) Patent Application Publication
(10) Pub. No.: US 2024/0413153 A1
(43) Pub. Date: Dec. 12, 2024

(54) System-On-Chip and Fabrication Method Therefor

(71) Applicants: Chengdu Analog Circuit Technology Inc., Sichuan (CN); Shanghai Analog Circuit Technology Co., Ltd., Shanghai (CN)

(72) Inventors: Dan Ning, Shanghai (CN); Jianjun Xiang, Sichuan (CN)

(21) Appl. No.: 18/602,426

(22) Filed: Mar. 12, 2024

(30) Foreign Application Priority Data
Jun. 12, 2023 (CN) 202310685324.2

(51) Int. Cl. H01L 27/092; H01L 21/8234; H01L 27/02; H10B 80/00

(52) U.S. Cl. CPC H01L 27/092; H01L 21/823462; H01L 27/0207; H10B 80/00

(57) ABSTRACT

A system-on-chip includes: an embedded memory module and its peripheral digital module, the embedded memory module includes at least one embedded memory cell, and the digital module includes at least one first MOS transistor and at least one standard cell; the standard cell includes at least one second MOS transistor, and the embedded memory cell includes at least one third MOS transistor, each of the first, second, and third MOS transistors includes a gate and a gate oxide layer underlying the gate, and the gate oxide layers of the second and third MOS transistors have the same thickness and are both thinner than the gate oxide layer of the first MOS transistor.

### CROSS-REFERENCE TO RELATED APPLICATION

This application claims priority to and benefits of Chinese Patent Application Serial No. 202310685324.2, filed with the National Intellectual Property Administration of PRC on Jun. 12, 2023, and all the benefits accruing therefrom under 35 U.S.C. 119, the entire content of which is incorporated herein by reference.

### TECHNICAL FIELD

The present disclosure relates to a system-on-chip and a fabrication method therefor, and specifically, to a system-on-chip including a digital module and an embedded memory module and a fabrication method therefor.

### BACKGROUND

A system-on-chip (SOC) includes a memory module and its peripheral digital module. There are two types of memory modules: embedded and non-embedded. An embedded memory module includes an embedded memory cell, and the memory cell includes a memory transistor. The peripheral digital module includes a logic transistor (also referred to as a peripheral logic transistor) and a standard cell. The standard cell also includes a logic transistor (also referred to as a peripheral logic transistor).

The peripheral logic transistor and the memory transistor are of different types, namely, a thick gate oxide layer and a thin gate oxide layer. Transistors with a thick gate oxide layer typically include 5 V devices, and transistors with a thin gate oxide layer typically include 1.5 V or 1.8 V devices. A transistor device with a thick gate oxide layer may be referred to as a high-voltage transistor device, and a transistor device with a thin gate oxide layer may be referred to as a low-voltage transistor device.

The peripheral standard cell and the embedded memory cell usually use a high-voltage device such as a 5 V transistor, or a low-voltage transistor such as a 1.5 V transistor. They have the following respective deficiencies. The high-voltage transistor has a thick gate oxide layer, a high threshold voltage, a large area, and a small unit capacitance, and is not suitable for a low voltage such as 5 V or lower. However, the low-voltage transistor has a low voltage resistance and is not suitable for a high voltage such as 1.5 V or higher.

Therefore, a new transistor with better structure and comprehensive performance is desired in the industry to be used in a peripheral standard cell and an embedded memory cell of a system-on-chip.

### SUMMARY

A first aspect of embodiments of the present disclosure relates to a system-on-chip, including: a digital module and an embedded memory module. The digital module includes at least one first metal-oxide-semiconductor (MOS) transistor and at least one standard cell, and the embedded memory module includes at least one embedded memory cell. The standard cell includes at least one second MOS transistor, and the embedded memory cell includes at least one third MOS transistor, each of the first MOS transistor, the second MOS transistor, and the third MOS transistors includes a gate and a gate oxide layer underlying the gate, and the gate oxide layers of the second MOS transistor and the third MOS transistor have a same thickness and are both thinner than the gate oxide layer of the first MOS transistor.

Another aspect of embodiments of the present disclosure relates to a method for fabricating the above-described system-on-chip of the present disclosure, including: forming a gate oxide layer of a first MOS transistor, thinning the formed gate oxide layer in regions where a second MOS transistor and a third MOS transistor are to be formed, and forming a gate oxide layer of the second MOS transistor and a gate oxide layer of the third MOS transistor.

### DETAILED DESCRIPTION

A system-on-chip includes a number of modules, each including a plurality of semiconductor devices such as transistors. Some modules further include some units composed of semiconductor devices (e.g., transistors).

A first aspect of embodiments of the present disclosure relates to a system-on-chip, including: a digital module and an embedded memory module. The digital module includes at least one first metal-oxide-semiconductor (MOS) transistor and at least one standard cell, and the embedded memory module includes at least one embedded memory cell. The standard cell includes at least one second MOS transistor, and the embedded memory cell includes at least one third MOS transistor, each of the first MOS transistor, the second MOS transistor, and the third MOS transistors includes a gate and a gate oxide layer underlying the gate, and the gate oxide layers of the second MOS transistor and the third MOS transistor have a same thickness and are both thinner than the gate oxide layer of the first MOS transistor.

In some embodiments, the thickness of the gate oxide layer of each of the second MOS transistor and the third MOS transistor is at least 10 angstroms less than that of the first MOS transistor.

In some embodiments, the thickness of the gate oxide layer of each of the second MOS transistor and the third MOS transistor is at least 20 angstroms less than that of the first MOS transistor.

In some embodiments, the gate oxide layers of the second MOS transistor and the third MOS transistor are formed in a same step in a same fabrication process platform.

In some embodiments, the digital module further includes a fourth MOS transistor, and the fourth MOS transistor includes a gate and a gate oxide layer underlying the gate. The gate oxide layer of the second MOS transistor is thicker than the gate oxide layer of the fourth MOS transistor.

In some embodiments, the thickness of the gate oxide layer of the second MOS transistor is at least 5 angstroms greater than that of the fourth MOS transistor.

In some embodiments, the thickness of the gate oxide layer of each of the second MOS transistor and the third MOS transistor ranges from 30 to 190 angstroms.

In some embodiments, the embedded memory cell is an embedded non-volatile memory cell.

In some embodiments, the embedded memory cell is an embedded multi-time erasable and programmable memory cell or an embedded flash memory cell.

In some embodiments, the standard cell is an inverter, a NAND gate, a NOR gate, a three-state buffer, a latch, a flip-flop, a register, a selector, or a full adder.

Another aspect of embodiments of the present disclosure relates to a method for fabricating the above-described system-on-chip of the present disclosure, including: forming a gate oxide layer of a first MOS transistor, thinning the formed gate oxide layer in regions where a second MOS transistor and a third MOS transistor are to be formed, and forming a gate oxide layer of the second MOS transistor and a gate oxide layer of the third MOS transistor.

In the following, the system-on-chip according to embodiments of the present disclosure and its fabrication method will be described in detail.

A system-on-chip of the present disclosure includes an embedded memory module and its peripheral digital module. A first MOS transistor and a fourth MOS transistor included in the digital module, and a second MOS transistor included in a standard cell may also be referred to as a thick-gate-oxide peripheral logic transistor, a thin-gate-oxide peripheral logic transistor, and an intermediate-gate-oxide peripheral logic transistor, respectively. A third MOS transistor included in a memory cell of the embedded memory module may also be referred to as an intermediate-gate-oxide memory transistor.

The first and fourth MOS transistors in the digital module are not included in the standard cell of the digital module.

In the system-on-chip of the present disclosure, a thickness of a gate oxide layer of the intermediate-gate-oxide peripheral logic transistor is equal to that of the intermediate-gate-oxide memory transistor, but less than that of the thick-gate-oxide peripheral logic transistor. When the digital module further includes a thin-gate-oxide peripheral logic transistor, the gate oxide layer of the intermediate-gate-oxide peripheral logic transistor is thinner than that of the thick-gate-oxide peripheral logic transistor, but thicker than that of the thin-gate-oxide peripheral logic transistor, that is, between the thicknesses of the gate oxide layer of the first MOS transistor and the thicknesses of the gate oxide layer of the fourth MOS transistors in the digital module.

The thickness of the gate oxide layer of the intermediate-gate-oxide peripheral logic transistor of the present disclosure is less than that of the thick-gate-oxide peripheral logic transistor in the digital module. As such, compared with the thick-gate-oxide peripheral logic transistor (i.e., a high-voltage transistor commonly used in a conventional peripheral standard cell), the intermediate-gate-oxide peripheral logic transistor has better performances, for example, allows for a smaller gate line width (a channel length), resulting in reduced area; has a lower threshold voltage, meeting the requirement of a medium or low operating voltage; and has better device characteristics such as a greater drive capability (drive current) and a larger unit capacitance.

In addition, the thickness of the gate oxide layer of the intermediate-gate-oxide peripheral logic transistor is greater than that of the thin-gate-oxide peripheral logic transistor in the digital module. As such, compared with the thin-gate-oxide peripheral logic transistor (i.e., a low-voltage transistor commonly used in a conventional peripheral standard cell), the intermediate-gate-oxide peripheral logic transistor has a higher voltage resistance and can meet the requirement of a slightly higher or medium operating voltage.

Similarly, compared with a thick-gate-oxide memory transistor, the intermediate-gate-oxide memory transistor of the present disclosure can reduce its operating voltage, reduce its occupied area, and reduce power consumption. Compared with a thin-gate-oxide memory transistor, the intermediate-gate-oxide memory transistor has a higher voltage resistance and can meet the requirement of a slightly higher or medium operating voltage.

In the present disclosure, the thickness of the gate oxide layer of the intermediate-gate-oxide peripheral logic transistor (i.e., the second MOS transistor) is at least 10 angstroms less than that of the thick-gate-oxide peripheral logic transistor (i.e., the first MOS transistor).

In some embodiments of the present disclosure, the thickness of the gate oxide layer of the intermediate-gate-oxide peripheral logic transistor (i.e., the second MOS transistor) is at least 20 angstroms less than that of the thick-gate-oxide peripheral logic transistor (i.e., the first MOS transistor).

In some embodiments of the present disclosure, the thickness of the gate oxide layer of the intermediate-gate-oxide peripheral logic transistor (i.e., the second MOS transistor) is at least 30 angstroms less than that of the thick-gate-oxide peripheral logic transistor (i.e., the first MOS transistor).

In the case where the digital module further includes the thin-gate-oxide peripheral logic transistor (i.e., the fourth MOS transistor), the thickness of the gate oxide layer of the intermediate-gate-oxide peripheral logic transistor is at least 5 angstroms greater than that of the thin-gate-oxide peripheral logic transistor.

In some embodiments of the present disclosure, the thickness of the gate oxide layer of the intermediate-gate-oxide peripheral logic transistor is at least 10 angstroms greater than that of the thin-gate-oxide peripheral logic transistor.

In some embodiments of the present disclosure, the thickness of the gate oxide layer of the intermediate-gate-oxide peripheral logic transistor is at least 20 angstroms greater than that of the thin-gate-oxide peripheral logic transistor.

In some embodiments of the present disclosure, the thickness of the gate oxide layer of the intermediate-gate-oxide peripheral logic transistor is at least 30 angstroms greater than that of the thin-gate-oxide peripheral logic transistor.

In some embodiments of the present disclosure, the thickness of the gate oxide layer of the intermediate-gate-oxide peripheral logic transistor is at least 50 angstroms, greater than that of the thin-gate-oxide peripheral logic transistor.

The thickness of the gate oxide layer of the intermediate-gate-oxide memory transistor has the same features as that of the intermediate-gate-oxide peripheral logic transistor described above.

In the present disclosure, specific values of the thicknesses of the gate oxide layers of the peripheral logic transistors and the memory transistor are not particularly limited, and depend on specific applications. However, the following values are provided as examples.

The thickness of the gate oxide layer of the thick-gate-oxide peripheral logic transistor (i.e., the first MOS transistor) is greater than 60 angstroms.

In some embodiments, the thickness of the gate oxide layer of the thick-gate-oxide peripheral logic transistor (i.e., the first MOS transistor) ranges from 70 to 300 angstroms.

In some embodiments, the thickness of the gate oxide layer of the thick-gate-oxide peripheral logic transistor (i.e., the first MOS transistor) ranges from 80 to 260 angstroms.

In some embodiments, the thickness of the gate oxide layer of the thick-gate-oxide peripheral logic transistor (i.e., the first MOS transistor) ranges from 90 to 220 angstroms.

In some embodiments, the thickness of the gate oxide layer of the thick-gate-oxide peripheral logic transistor (i.e., the first MOS transistor) ranges from 100 to 180 angstroms.

The thickness of the gate oxide layer of each of the intermediate-gate-oxide peripheral logic transistor (i.e., the second MOS transistor) and the intermediate-gate-oxide memory transistor (i.e., the third MOS transistor) ranges from 30 to 190 angstroms.

In some embodiments, the thickness of the gate oxide layer of each of the intermediate-gate-oxide peripheral logic transistor (i.e., the second MOS transistor) and the intermediate-gate-oxide memory transistor (i.e., the third MOS transistor) ranges from 40 to 150 angstroms.

In some embodiments, the thickness of the gate oxide layer of each of the intermediate-gate-oxide peripheral logic transistor (i.e., the second MOS transistor) and the intermediate-gate-oxide memory transistor (i.e., the third MOS transistor) ranges from 50 to 110 angstroms.

In some embodiments, the thickness of the gate oxide layer of each of the intermediate-gate-oxide peripheral logic transistor (i.e., the second MOS transistor) and the intermediate-gate-oxide memory transistor (i.e., the third MOS transistor) ranges from 55 to 100 angstroms.

In some embodiments, the thickness of the gate oxide layer of each of the intermediate-gate-oxide peripheral logic transistor (i.e., the second MOS transistor) and the intermediate-gate-oxide memory transistor (i.e., the third MOS transistor) ranges from 60 to 90 angstroms.

The thickness of the gate oxide layer of the thin-gate-oxide peripheral logic transistor (i.e., the fourth MOS transistor) ranges from 10 to 40 angstroms.

In some embodiments, the thickness of the gate oxide layer of the thin-gate-oxide peripheral logic transistor (i.e., the fourth MOS transistor) ranges from 12 to 38 angstroms.

In some embodiments, the thickness of the gate oxide layer of the thin-gate-oxide peripheral logic transistor (i.e., the fourth MOS transistor) ranges from 15 to 35 angstroms.

In some embodiments, the thickness of the gate oxide layer of the thin-gate-oxide peripheral logic transistor (i.e., the fourth MOS transistor) ranges from 18 to 32 angstroms.

In the present disclosure, a gate line width (channel length) of each of the intermediate-gate-oxide peripheral logic transistor and the intermediate-gate-oxide memory transistor is less than that of the thick-gate-oxide peripheral logic transistor. In the case where the digital module includes both the thick-gate-oxide peripheral logic transistor and the thin-gate-oxide peripheral logic transistor, the gate line width (channel length) of the intermediate-gate-oxide peripheral logic transistor is less than that of the thick-gate-oxide peripheral logic transistor, but greater than that of the thin-gate-oxide peripheral logic transistor, that is, between the gate line width of the thin-gate-oxide peripheral logic transistor and the gate line width of thick-gate-oxide peripheral logic transistor.

In the present disclosure, specific values of the gate line widths (channel lengths) of the peripheral logic transistors and the memory transistor are not particularly limited, and depend on specific applications. However, the following values are provided as examples.

The gate line width (channel length) of the thick-gate-oxide peripheral logic transistor ranges from 0.11 μm to 12.00 μm.

In some embodiments, the gate line width (channel length) of the thick-gate-oxide peripheral logic transistor ranges from 0.15 μm to 7.00 μm.

In some embodiments, the gate line width (channel length) of the thick-gate-oxide peripheral logic transistor ranges from 0.20 μm to 2.00 μm.

In some embodiments, the gate line width (channel length) of the thick-gate-oxide peripheral logic transistor ranges from 0.30 μm to 0.8 μm.

The gate line width (channel length) of each of the intermediate-gate-oxide peripheral logic transistor and the intermediate-gate-oxide memory transistor ranges from 0.05 μm to 10.00 μm.

In some embodiments, the gate line width (channel length) of each of the intermediate-gate-oxide peripheral logic transistor and the intermediate-gate-oxide memory transistor ranges from 0.08 μm to 5.00 μm.

In some embodiments, the gate line width (channel length) of each of the intermediate-gate-oxide peripheral logic transistor and the intermediate-gate-oxide memory transistor ranges from 0.11 μm to 1.00 μm.

In some embodiments, the gate line width (channel length) of each of the intermediate-gate-oxide peripheral logic transistor and the intermediate-gate-oxide memory transistor ranges from 0.13 μm to 0.60 μm.

The gate line width (channel length) of the thin-gate-oxide peripheral logic transistor ranges from 0.01 μm to 5.00 μm.

In some embodiments, the gate line width (channel length) of the thin-gate-oxide peripheral logic transistor ranges from 0.03 μm to 1.00 μm.

In some embodiments, the gate line width (channel length) of the thin-gate-oxide peripheral logic transistor ranges from 0.05 μm to 0.5 μm.

In some embodiments, the gate line width (channel length) of the thin-gate-oxide peripheral logic transistor ranges from 0.07 μm to 0.20 μm.

In the system-on-chip of the present disclosure, the peripheral logic transistors in the digital module and the memory transistor in the memory module are fabricated in a same fabrication process platform. That is, the thick-gate-oxide peripheral logic transistor, the intermediate-gate-oxide peripheral logic transistor, and the intermediate-gate-oxide memory transistor are fabricated in the same fabrication process platform. In the case where the digital module further includes the thin-gate-oxide peripheral logic transistor, the thin-gate-oxide peripheral logic transistor is also fabricated in the same fabrication process platform. The gate oxide layers of the intermediate-gate-oxide peripheral logic transistor and the intermediate-gate-oxide memory transistor are formed together in the same step in the same fabrication process. In addition, steps such as well implantation, gate formation, and light doping and heavy doping of a source and a drain for the intermediate-gate-oxide peripheral logic transistor and the intermediate-gate-oxide memory transistor are respectively performed together with the corresponding steps for the thick-gate-oxide peripheral logic transistor. The difference lies in that when these transistors are of different types, ions for the well implantation, the source doping and the drain doping are of different types. Such a fabrication method is very convenient, and can not only improve the efficiency, but also reduce the cost. However, formation of a new transistor device in a chip known in the industry usually requires an additional gate oxide layer formation step, as well as additional well implantation, source doping and drain doping steps. The technical solution of the present disclosure reduces the process complexity and saves photomask layers.

In other words, on an embedded memory module platform based on a logic process, embodiments of the present disclosure allow for a tunneling oxide layer in the memory cell to be utilized as the gate oxide layer of the intermediate-gate-oxide peripheral logic transistor, and allow the preparation of the intermediate-gate-oxide peripheral logic transistor to share the well implantation process, the light doping and heavy doping processes of source and drain, etc. with the preparation of a thick-gate-oxide standard logic device in the process platform, so that a new transistor or transistor capacitor is formed. The new transistor has a thinner gate oxide layer, a lower threshold voltage, and can work at a lower operating voltage. The new device (i.e., the new transistor) has a smaller design rule, and a standard cell based on this process platform may have a smaller area when using the new device, which can greatly reduce the product cost.

The system-on-chip of the present disclosure may be fabricated by a plurality of standard logic process platforms in the industry, such as 180 nm, 150 nm, 130 nm, 110 nm, 90 nm, 55 nm, or 40 nm process platform. The 180 nm process can fabricate a 5 V or 3.3 V transistor device, or simultaneously fabricate 1.8 V and 5 V transistor devices, or simultaneously fabricate 1.8 V and 3.3 V transistor devices. The 110 nm process can fabricate a 5 V transistor device, or simultaneously fabricate 1.5 V and 5 V transistor devices.

These processes generally include the following steps in sequence: forming a shallow trench isolation region, successively forming wells where thick-gate-oxide and thin-gate-oxide transistors are located, forming a thick gate oxide layer, forming a thin gate oxide layer (specifically including: using a mask to cover regions other than the thin-gate-oxide transistor region, and then in the thin-gate-oxide transistor region that is not covered with the mask, thinning the thick gate oxide layer to form the thin gate oxide layer), forming gates, successively forming a lightly doped region of the source and drain of each of the thin-gate-oxide and thick-gate-oxide transistors, forming a gate sidewall protection layer, forming a heavily doped region of the source and drain of each of the thin-gate-oxide and thick-gate-oxide transistors, forming metal silicide, and forming a back-end metal interconnecting layer.

In the case where the digital module does not include the thin-gate-oxide peripheral logic transistor, the above steps do not include the steps related to the thin-gate-oxide transistor.

More specifically, in the case where the digital module in the system-on-chip does not include the thin-gate-oxide peripheral logic transistor, the steps of forming the intermediate-gate-oxide peripheral logic transistor and the intermediate-gate-oxide memory transistor of the present disclosure are as follows.

In the process for fabricating the system-on-chip of the present disclosure, wells where the intermediate-gate-oxide peripheral logic t transistor and the intermediate-gate-oxide memory transistor are located, as well as gates, sources and drains of the intermediate-gate-oxide peripheral logic transistor and the intermediate-gate-oxide memory transistor are respectively formed together with the formation of a well, a gate, a source and a drain of the thick-gate-oxide peripheral logic transistor. The difference lies in that when the intermediate-gate-oxide peripheral logic transistor is of a different type from the intermediate-gate-oxide memory transistor or the thick-gate-oxide peripheral logic transistor, ions for well implantation, source doping and drain doping of the intermediate-gate-oxide peripheral logic transistor are of different types from that of the intermediate-gate-oxide memory transistor or the thick-gate-oxide peripheral logic transistor.

The gate oxide layers of the intermediate-gate-oxide peripheral logic transistor and the intermediate-gate-oxide memory transistor are the same, and are formed together in the same step. However, they are different from the gate oxide layer of the thick-gate-oxide peripheral logic transistor, and they are formed at a different time from that when the gate oxide layer of the thick-gate-oxide peripheral logic transistor is formed. That is, between the formation of the wells and the formation of the gates, in the step of forming the gate oxide layers, after the gate oxide layer of the thick-gate-oxide peripheral logic transistor is formed, regions other than those regions where the intermediate-gate-oxide peripheral logic transistor and the intermediate-gate-oxide memory transistor are to be formed are covered with a mask, and then in the regions where the mask does not cover and the intermediate-gate-oxide peripheral logic transistor and the intermediate-gate-oxide memory transistor are to be formed, the thick gate oxide layer that has been formed is thinned to a required thickness to form new thin intermediate-gate-oxide layers.

A first implementation of thinning the thick-gate-oxide layer in regions not covered with the mask and forming the new intermediate-gate-oxide layers includes: applying illumination in the regions not covered with the mask, etching these regions to completely remove the gate oxide layer in these regions, and then performing thermal oxidation in these regions to a required thickness to generate new gate oxide layers. Alternatively, a second implementation includes: applying illumination in the regions not covered with the mask, and etching these regions to partially remove the gate oxide layer in these regions, until the remaining gate oxide layer in these regions reaches the required thickness of the new gate oxide layers. The first implementation is preferred. This is because in the second implementation, the gate oxide layer is partially removed, and an etched substance may be retained in the remaining gate oxide layer, which affects the performance of the new gate oxide layers.

In the case where the digital module of the system-on-chip further includes the thin-gate-oxide peripheral logic transistor, in the fabrication process, the formation of the well, the gate oxide layer, the gate, and doped regions of the source and the drain of each of the intermediate-gate-oxide peripheral logic transistor and the intermediate-gate-oxide memory transistor is still the same as described above. The gate oxide layer of the thin-gate-oxide peripheral logic transistor is formed as follows. In the step of forming the gate oxide layers, after the gate oxide layers of the thick-gate-oxide peripheral logic transistor and the intermediate-gate-oxide peripheral logic transistor are formed, regions other than a region where the thin-gate-oxide peripheral logic transistor is to be formed are covered with a mask, and then in the region where the mask does not cover and the thin-gate-oxide peripheral logic transistor region is to be formed, the gate oxide layer is thinned to a thickness required by the gate oxide layer of the thin-gate-oxide peripheral logic transistor. Then the gate is formed.

The implementations of thinning the gate oxide layer in the region not covered with the mask and forming the new gate oxide layer in the region not covered with the mask are the same as described above.

The embedded memory cell of the present disclosure is preferably an embedded non-volatile memory cell. In some embodiments, the embedded memory cell is an embedded multi-time erasable and programmable memory cell or an embedded flash memory cell.

The standard cell in the digital module of the present disclosure is an inverter, a NAND gate, a NOR gate, a three-state buffer, a latch, a flip-flop, a register, a selector, or a full adder.

The system-on-chip of the present disclosure and a fabrication method therefor, a fabrication method for the intermediate-gate-oxide peripheral logic transistor and the intermediate-gate-oxide memory transistor therein, and a structure and performance thereof are described in detail below by way of embodiments.

In some embodiments, a system-on-chip is fabricated using a 110 nm logic process. The system-on-chip includes an embedded multi-time erasable and programmable memory module and its peripheral digital module. The memory module includes at least one embedded multi-time erasable and programmable memory cell, and each memory cell includes an intermediate-gate-oxide memory transistor. The digital module includes: at least one thick-gate-oxide peripheral logic transistor, at least one thin-gate-oxide peripheral logic transistor, and at least one standard cell. The at least one standard cell is an inverter. The inverter includes two intermediate-gate-oxide peripheral logic transistors that are basically the same in structure and composition but of opposite types, i.e., an NMOS intermediate-gate-oxide peripheral logic transistor and a PMOS intermediate-gate-oxide peripheral logic transistor.

The thick-gate-oxide peripheral logic transistor, the thin-gate-oxide peripheral logic transistor, the NMOS intermediate-gate-oxide peripheral logic transistor in the inverter, and the intermediate-gate-oxide memory transistor are all NMOS transistors located in a P well, and each have N-type source and drain, and each pair of source and drain include an N-type lightly doped region and an N-type heavily doped region. The thick-gate-oxide peripheral logic transistor has a gate oxide layer with a thickness of 139±5 angstroms, is suitable for an operating voltage of 5 V, and may be referred to as a 5 V transistor device. The thin-gate-oxide peripheral logic transistor has a gate oxide layer with a thickness of 25±5 angstroms, is suitable for an operating voltage of 1.5 V, and may be referred to as a 1.5 V transistor device. The NMOS intermediate-gate-oxide peripheral logic transistor in the inverter has a gate oxide layer with a thickness of 85±5 angstroms, is suitable for an operating voltage of 3.3 V, and may be referred to as a 3.3 V transistor device. The intermediate-gate-oxide memory transistor has a gate oxide layer with a thickness of 85±5 angstroms, is suitable for an operating voltage of 3.3 V, and may be referred to as a 3.3 V transistor device. The PMOS intermediate-gate-oxide peripheral logic transistor in the inverter is located in an N well and has P-type source and drain, and the pair of the source and drain include a P-type lightly doped region and a P-type heavily doped region. The gate oxide layer of the PMOS intermediate-gate-oxide peripheral logic transistor also has a thickness of 85±5 angstroms, the same as the NMOS.

Compared with a thick-gate-oxide peripheral logic transistor (such as a 5 V transistor device) commonly used in a conventional peripheral standard cell, the gate oxide layers of the NMOS and PMOS intermediate-gate-oxide peripheral logic transistors in this embodiment are thinner than that of the thick-gate-oxide peripheral logic transistor, and the NMOS and PMOS intermediate-gate-oxide peripheral logic transistors both have a lower threshold voltage and can be used for an operating voltage of 3.3 V lower than 5 V, meeting the requirement of a low operating voltage. In addition, compared with a thin-gate-oxide peripheral logic transistor (such as a 1.5 V transistor device) commonly used in a conventional peripheral standard cell, the gate oxide layers of the NMOS and PMOS intermediate-gate-oxide peripheral logic transistors in this embodiment are thicker than that of the thin-gate-oxide peripheral logic transistor, and their voltage resistance is enhanced, so that the NMOS and PMOS intermediate-gate-oxide peripheral logic transistors are suitable for an operating voltage of 3.3 V higher than 1.5 V.

In this embodiment, the thick-gate-oxide peripheral logic transistor has a gate line width (channel length) of 0.6 μm, the thin-gate-oxide peripheral logic transistor has a gate line width (channel length) of 0.11 μm, the NMOS and PMOS intermediate-gate-oxide peripheral logic transistors have the same gate line width (channel length) of 0.35 μm, and the intermediate-gate-oxide memory transistor has a gate line width (channel length) of 0.35 μm. The gate line width (channel length) of each intermediate-gate-oxide peripheral logic transistor is less than that of the thick-gate-oxide peripheral logic transistor. Compared with a thick-gate-oxide peripheral logic transistor commonly used in the conventional peripheral standard cell, an area of the intermediate-gate-oxide peripheral logic transistor in this embodiment can be reduced. The intermediate-gate-oxide memory transistor can also reduce an area of the memory cell.

In addition, in this embodiment, channel saturation currents of the thick-gate-oxide peripheral logic transistor, the thin-gate-oxide peripheral logic transistor, the NMOS intermediate-gate-oxide peripheral logic transistor, the PMOS intermediate-gate-oxide peripheral logic transistor, and the intermediate-gate-oxide memory transistor are 570 μA/μm, 425 μA/μm, 530 μA/μm, −260 μA/μm, and 530 μA/μm, respectively. The channel saturation current of the NMOS intermediate-gate-oxide peripheral logic transistor is greater than that of the thin-gate-oxide peripheral logic transistor. Compared with a thin-gate-oxide peripheral logic transistor commonly used in the conventional peripheral standard cell, the NMOS intermediate-gate-oxide peripheral logic transistor in this embodiment has a greater drive capability (drive current) at the same operating voltage.

The system-on-chip according to this embodiment is fabricated using a 110 nm logic process platform. The fabrication method includes the following steps in sequence: forming a shallow trench isolation region, forming an N well where the PMOS intermediate-gate-oxide peripheral logic transistor is located, forming a P well where the thick-gate-oxide peripheral logic transistor, the NMOS intermediate-gate-oxide peripheral logic transistor, and the intermediate-gate-oxide memory transistor are located, forming a P well where the thin-gate-oxide peripheral logic transistor is located, forming the gate oxide layers (including: successively forming the gate oxide layer of the thick-gate-oxide peripheral logic transistor, the gate oxide layers of the PMOS and NMOS intermediate-gate-oxide peripheral logic transistors and the intermediate-gate-oxide memory transistor, and the gate oxide layer of the thin-gate-oxide peripheral logic transistor), forming gates of the five transistors, forming a lightly doped region of N-type source and drain of the thin-gate-oxide peripheral logic transistor, forming a lightly doped region of N-type source and drain of each of the thick-gate-oxide peripheral logic transistor, the NMOS intermediate-gate-oxide peripheral logic transistor and the intermediate-gate-oxide memory transistor, forming a lightly doped region of P-type source and drain of the PMOS intermediate-gate-oxide peripheral logic transistor, forming a gate sidewall protection layer, forming a heavily doped region of the source and drain of each of the five transistors, forming metal silicide, and forming a back-end metal interconnecting layer.

The intermediate-gate-oxide peripheral logic transistors and the intermediate-gate-oxide memory transistor are basically formed together with the thick-gate-oxide peripheral logic transistor (high-voltage transistor). The well where the NMOS intermediate-gate-oxide peripheral logic transistor and the intermediate-gate-oxide memory transistor are located, and the gates, the sources and the drains of the NMOS intermediate-gate-oxide peripheral logic transistor and the intermediate-gate-oxide memory transistor are respectively formed together with the formation of the well, the gate, the source and the drain of the thick-gate-oxide peripheral logic transistor. The N well of the PMOS intermediate-gate-oxide peripheral logic transistor is formed before the formation of the P well of the thick-gate-oxide peripheral logic transistor; and the gate, the source and the drain of the PMOS intermediate-gate-oxide peripheral logic transistor are also respectively formed together with the formation of the gate, the source and the drain of the thick-gate-oxide peripheral logic transistor.

However, the formation of the gate oxide layers of the intermediate-gate-oxide peripheral logic transistors and the intermediate-gate-oxide memory transistor is different from that of the gate oxide layer of the thick-gate-oxide peripheral logic transistor. The steps for forming the gate oxide layers of these transistors are specifically as follows.

Between the formation of the wells and the formation of the gates, in the step of forming the gate oxide layers, the gate oxide layer with a thickness of 139±5 angstroms of the thick-gate-oxide peripheral logic transistor is first formed. Then, regions other than those regions where the intermediate-gate-oxide peripheral logic transistors and the intermediate-gate-oxide memory transistor are to be formed are covered with a mask, and then the regions where the mask does not cover and the intermediate-gate-oxide peripheral logic transistors and the intermediate-gate-oxide memory transistor are to be formed are illuminated and etched to completely remove the thick gate oxide layer, and then subjected to thermal oxidation to generate new gate oxide layers each having a thickness of 85±5 angstroms, i.e., the gate oxide layers of the intermediate-gate-oxide peripheral logic transistors and the intermediate-gate-oxide memory transistor. Subsequently, the gate oxide layer of the thin-gate-oxide peripheral logic transistor is directly formed. That is, regions other than a region where the thin-gate-oxide peripheral logic transistor is to be formed are covered with a mask, and then the region where the mask does not cover and the thin-gate-oxide peripheral logic transistor is to be formed is illuminated and etched to completely remove the gate oxide layer, and then subjected to thermal oxidation to generate a new gate oxide layer with a thickness of 25±5 angstroms, i.e., the gate oxide layer of the thin-gate-oxide peripheral logic transistor.

The present disclosure provides a convenient, high-efficiency, and low-cost method to simultaneously fabricate the new intermediate-gate-oxide peripheral logic transistor and intermediate-gate-oxide memory transistor with better performances, which are used in the peripheral digital module and the embedded memory module of the system-on-chip, respectively.

What is claimed is:

1. A system-on-chip, comprising:
a digital module and an embedded memory module, wherein the digital module comprises at least one first metal-oxide-semiconductor (MOS) transistor and at least one standard cell, and the embedded memory module comprises at least one embedded memory cell; and
wherein the standard cell comprises at least one second MOS transistor, and the embedded memory cell comprises at least one third MOS transistor, each of the first MOS transistor, the second MOS transistor, and the third MOS transistor comprises a gate and a gate oxide layer underlying the gate, and the gate oxide layers of the second MOS transistor and the third MOS transistors have a same thickness and are both thinner than the gate oxide layer of the first MOS transistor.

2. The system-on-chip according to claim 1, wherein the thickness of the gate oxide layer of each of the second MOS transistor and the third MOS transistor is at least 10 angstroms less than that of the first MOS transistor.

3. The system-on-chip according to claim 1, wherein the gate oxide layers of the second MOS transistor and the third MOS transistor are formed in a same step in a same fabrication process platform.

4. The system-on-chip according to claim 1, wherein the digital module further comprises a fourth MOS transistor, the fourth MOS transistor comprises a gate and a gate oxide layer underlying the gate, and the gate oxide layer of the second MOS transistor is thicker than the gate oxide layer of the fourth MOS transistor.

5. The system-on-chip according to claim 4, wherein the thickness of the gate oxide layer of the second MOS transistor is at least 5 angstroms greater than that of the fourth MOS transistor.

6. The system-on-chip according to claim 1, wherein the thickness of the gate oxide layer of each of the second MOS transistor and the third MOS transistor ranges from 30 to 190 angstroms.

7. The system-on-chip according to claim 1, wherein the embedded memory cell is an embedded non-volatile memory cell.

8. The system-on-chip according to claim 7, wherein the embedded non-volatile memory cell is an embedded multi-time erasable and programmable memory cell or an embedded flash memory cell.

9. The system-on-chip according to claim 1, wherein the standard cell is an inverter, a NAND gate, a NOR gate, a three-state buffer, a latch, a flip-flop, a register, a selector, or a full adder.

10. The system-on-chip according to claim 1, wherein a gate line wide of the second MOS transistor is less than that of the first MOS transistor, and a gate line wide of the third MOS transistor is less than that of the first MOS transistor.

11. The system-on-chip according to claim 10, wherein the gate line wide of each of the second MOS transistor and the third MOS transistor range from 0.05 to 10.00 μm.

12. The system-on-chip according to claim 4, wherein a gate line wide of the second MOS transistor is less than that of the first MOS transistor, and greater than that of the fourth MOS transistor; and
a gate line wide of the third MOS transistor is less than that of the first MOS transistor, and greater than that of the fourth MOS transistor.

13. The system-on-chip according to claim 12, wherein the gate line wide of each of the second MOS transistor and the third MOS transistor range from 0.05 to 10.00 μm.

14. The system-on-chip according to claim 1, wherein the standard cell comprises an NMOS transistor and a PMOS transistor, and the NMOS transistor and the PMOS transistor each have a gate oxide layer thinner than that of the first transistor.

15. The system-on-chip according to claim 14, wherein the gate oxide layers of the NMOS transistor, the PMOS transistor and the third MOS transistors have a same thickness.

16. The system-on-chip according to claim 4, wherein the standard cell comprises an NMOS transistor and a PMOS transistor, and the NMOS transistor and the PMOS transistor each have a gate oxide layer thinner than that of the first transistor and thicker than that of the fourth MOS transistor.

17. The system-on-chip according to claim 16, wherein the gate oxide layers of the NMOS transistor, the PMOS transistor and the third MOS transistors have a same thickness.

18. The system-on-chip according to claim 16, wherein a thickness of the gate oxide layer of each of the NMOS transistor and the PMOS transistor is at least 10 angstroms less than that of the first MOS transistor, and is at least 5 angstroms greater than that of the fourth MOS transistor.

19. A method for fabricating the system-on-chip according to claim 1, comprising:
forming a gate oxide layer of a first MOS transistor, thinning the formed gate oxide layer in regions where a second MOS transistor and a third MOS transistor are to be formed to simultaneously form a gate oxide layer of the second MOS transistor and a gate oxide layer of the third MOS transistor.

20. The method according to claim 19, after forming the gate oxide layer of the second MOS transistor and the gate oxide layer of the third MOS transistor, further comprising: thinning a region where a fourth MOS transistor is to be formed to form a gate oxide layer of the fourth MOS transistor, such that the gate oxide layer of the fourth MOS transistor is thinner than both the gate oxide layer of the second MOS transistor and the gate oxide layer of the third MOS transistor.
